(19) United States
(12) Patent Application Publication
(10) Pub. No.: US 2016/0346608 A1
(43) Pub. Date: Dec. 1, 2016

(54) GARMENTS HAVING ARTICLES SECURED THERETO AND METHODS FOR SECURING THE ARTICLES TO THE GARMENTS

(71) Applicant: GestureLogic Inc., Ottawa (CA)

(72) Inventors: Timothy Alan Inglis, Ottawa (CA); Michelle Hui Jun Zheng, Mississauga (CA); James Henderson, Kanata (CA); Kevin Bailey, Ottawa (CA)

(73) Assignee: GestureLogic Inc.

(21) Appl. No.: 14/722,851

(22) Filed: May 27, 2015

(51) Int. Cl. A63B 24/00; H05K 5/02; B29C 45/14

(52) U.S. Cl. CPC A63B 24/0062; B29C 45/14786; H05K 5/0217; B29K 2713/00; B29L 2031/48

(57) ABSTRACT

A method for securing a rigid or semi-rigid article to a textile is described. The method can include the steps of positioning the article in a mold cavity of a mold; laying the textile between opposed mold portions for forming the mold cavity with a textile region of the textile extending across the mold cavity; closing the mold to clamp the textile between the opposed mold portions and substantially seal the article and the textile region in the mold cavity; filling the mold cavity with moldable material; and curing the moldable material to form an enclosure undetachably molded over the article and the textile region and embedding the article.

### FIELD

The various embodiments described herein generally relate to garments having rigid or semi-rigid articles secured thereto, and methods for securing the articles to the garments.

### BACKGROUND

In recent years, devices capable of monitoring an individual's physical and physiological state have become increasingly popular. Monitoring and maintaining physical fitness is an ongoing concern for individuals with busy lifestyles, and this concern is becoming more pronounced with an aging population. As a result, demand is increasing for fitness devices that can track physical activities and individual fitness.

Attempts have been made to attach such devices to garments worn by a user to monitor the user's physiological state during physical activity. However, current methods of attaching such devices for this purpose may fail to robustly secure the device to the garment, adequately seal it from adverse environmental conditions, or both.

### SUMMARY OF VARIOUS EMBODIMENTS

In a broad aspect, at least one embodiment described herein provides a method for securing a rigid or semi-rigid article to a textile. The method can include the steps of (a) positioning the article in a mold cavity of a mold; (b) laying the textile between opposed mold portions for forming the mold cavity with a textile region of the textile extending across the mold cavity; (c) closing the mold to clamp the textile between the opposed mold portions and substantially seal the article and the textile region in the mold cavity; (d) filling the mold cavity with moldable material; and (e) curing the moldable material to form an enclosure undetachably molded over the article and the textile region and embedding the article.

In some embodiments, the enclosure can environmentally seal the article.

In some embodiments, the mold cavity can surround opposing surfaces of the textile region when the mold is closed, and the enclosure can be molded over the opposing surfaces.

In some embodiments, the filling step can further comprise forcing the moldable material to permeate the textile region.

In some embodiments, the method can further comprise, prior to the filling step, forming perforations in the textile region to facilitate flow of the moldable material through the textile region during the filling step.

In some embodiments, the laying step can further comprise smoothing out the textile region.

In some embodiments, flattening the textile can comprise applying tension to the textile to flatten the textile region across the mold cavity.

In some embodiments, the article can comprise a housing enclosing an electronics module.

In some embodiments, the method can further comprise, prior to the filling step, positioning a base of the housing against the textile region, and supporting the base against the textile region during the filling step.

In some embodiments, the method can further comprise, prior to the filling step, adhering the base of the housing to the textile region.

In some embodiments, the method can further comprise forming perforations adjacent a periphery of the base through the textile region for permitting flow of the moldable material through the textile region during the filling step.

In some embodiments, the method can further comprise, prior to the closing step, forming an encapsulating shell around the housing, the shell impeding moldable material from flowing into the housing during the filling step.

In some embodiments, the positioning step can further comprise engaging an engagement structure of the housing with a cooperating engagement structure of the mold to support the housing within the mold cavity in a floating configuration in which unengaged portions of the housing are spaced apart from inner surfaces defining the mold cavity when the mold is closed.

In some embodiments, the engagement structure of the housing can comprise a port extending through the housing for operatively coupling an external cable to the electronics module, and the engagement member of the mold can comprise a plug insertable into the port. The port and the plug can engage to support the housing within the mold cavity in the floating configuration and impede flow of the moldable material into the port during the filling step.

In some embodiments, the engagement structure of the housing can comprise a tapped hole and the engagement structure of the mold can comprise a threaded fastener extending into the mold cavity for engaging the tapped hole to support the housing within the mold cavity in the floating configuration.

In some embodiments, the method can further comprise, prior to the filling step, injecting a potting material into the housing to reduce air space within the housing.

In some embodiments, the housing can be positioned below the textile region during the filling step.

In some embodiments, the textile can comprise an integrated signal-transfer line, and the method can further comprise, prior to the closing step, operatively coupling the signal-transfer line to the electronics module.

In some embodiments, the method can further comprise, prior to the closing step, feeding an end portion of the signal-transfer line through the housing and operatively coupling the end portion to the electronics module.

In some embodiments, the textile can be an elastically stretchable textile, and the signal-transfer line is woven through the textile in a crimped pattern permitting the signal-transfer line to straighten out to accommodate stretching of the textile.

In some embodiments, the signal-transfer line can be conductive and insulated.

In some embodiments, the signal-transfer line can comprise a conductive yarn woven through the textile.

In some embodiments, an electrode can be secured to the textile. The electrode can be operable to acquire electrical signals from a skin surface region of a user wearing the textile. The method can further comprise operatively coupling the electrode and the electronics module via the signal-transfer line.

In some embodiments, the filling step can further comprise injecting the moldable material under pressure into the mold cavity.

In some embodiments, the method can further comprise, after the filling step, placing the enclosure inside a pressure vessel having a pressure suitable to reduce occurrence of visible air bubble formations in the formed enclosure.

In some embodiments, the method can further comprise, prior to the filling step, vacuum degassing the moldable material.

In some embodiments, the moldable material can comprise a low viscosity material.

In some embodiments, the moldable material can be a room temperature vulcanization polymer.

In some embodiments, the moldable material can be a urethane rubber.

In some embodiments, the moldable material can be silicone.

In another broad aspect, at least one embodiment described herein provides a garment comprising a textile and a rigid or semi-rigid article secured to the textile according to the method described above.

In another broad aspect, at least one embodiment described herein provides a garment comprising (a) a textile; (b) a rigid or semi-rigid article; and (c) an enclosure undetachably molded over the article and a textile region of the textile, and embedding the article.

In some embodiments, the enclosure can environmentally seal the article.

In some embodiments, the enclosure can be integrally formed and comprise a first portion and a second portion molded over opposing surfaces, respectively, of the textile region, and bonding portions extending between the first and second portions through the textile.

In some embodiments, the bonding portions can permeate the textile region.

In some embodiments, the bonding portions can extend between the first and second portions through perforations in the textile region.

In some embodiments, a surface of the article can be adhered to the textile region and the perforations can be adjacent a periphery of the surface.

In some embodiments, the article can comprise a housing enclosing an electronics module.

In some embodiments, depression of the enclosure can actuate the electronics module.

In some embodiments, the housing can comprise a base adjacent the textile region, a wall extending upwardly from a periphery of the base, and an actuator enclosing a top of the housing. The actuator can be depressible to actuate the electronics module through depression of the enclosure.

In some embodiments, an actuator can be supported within the housing. A portion of the actuator can extend through an aperture of the housing and can be depressible to actuate the electronics module through depression of the enclosure.

In some examples, the housing can comprise a base adjacent the textile region, a wall extending upwardly from a periphery of the base, and a lid enclosing a top of the housing and comprising the aperture.

In some embodiments, the enclosure can comprise an opening exposing a port of the housing for operatively coupling an external module to the electronics module.

In some embodiments, the garment can further comprise a signal-transfer line integrated into the textile and operatively coupled to the electronics module.

In some embodiments, an end portion of the signal-transfer line can extend through the housing and be operatively coupled to the electronics module.

In some embodiments, the textile can be an elastically stretchable textile, and the signal-transfer line can be woven through the textile in a crimped pattern permitting the signal-transfer line to straighten out to accommodate stretching of the textile.

In some embodiments, the signal-transfer line can be conductive and insulated.

In some embodiments, the signal-transfer line can comprise a conductive yarn woven through the textile.

In some embodiments, the garment can further comprise an electrode mounted to the textile, and the signal-transfer line can operatively couple the electrode and the electronics module.

In some embodiments, the electrode can be positioned to acquire an electrical signal from a skin surface region of a user wearing the garment, and the electronics module can comprise a controller coupled to the electrode through the signal-transfer line and configured to receive electrical signals from the electrode and process the signals to determine at least one biometric.

In some embodiments, the electronics module can further comprise a wireless communication unit operatively coupled to the controller to communicate with a remote processing device. At least one of the controller and the remote processing device can be configured to receive electrical signals from the electrode and process the signals to determine at least one biometric.

In some embodiments, the garment can be a compression garment for applying compressive pressures against a body part.

In some embodiments, the enclosure can be formed from a cured moldable material.

### BRIEF DESCRIPTION OF THE DRAWINGS

For a better understanding of the various embodiments described herein, and to show more clearly how these various embodiments may be carried into effect, reference will be made, by way of example, to the accompanying drawings which show at least one example embodiment, and which are now briefly described.

FIG. 1 is a perspective view of an example garment.

FIG. 2 is a diagram illustrating example placements on a user's body of the garment of FIG. 1.

FIG. 3A is an example portion of a textile of the garment of FIG. 1 in an unstretched configuration.

FIG. 3B is the example portion of the textile of FIG. 3A in a stretched configuration.

FIG. 4 is a cross sectional view of a portion of the garment of FIG. 1 taken along line 4-4 of FIG. 1.

FIG. 5 is an exploded view of an example housing enclosing an example electronics module of the garment of FIG. 1.

FIG. 6 is a top view of an example housing body of the housing of FIG. 5.

FIG. 7 is a block diagram illustrating various components of the electronics module of FIG. 5.

FIG. 8 is a sectional view of an example housing body of the housing of FIG. 5 being positioned on a textile region of the garment of FIG. 1 according to an aspect of an embodiment.

FIG. 9 is a sectional view of the housing of FIG. 5 positioned on a textile region of the garment of FIG. 1 according to an aspect of an embodiment.

FIG. 10A is a sectional view of the housing of FIG. 5 positioned on a textile region of the garment of FIG. 1 with formed perforations according to an aspect of an embodiment.

FIG. 10B is a perspective view of the housing of FIG. 10A positioned on the textile region of the garment of FIG. 1 with formed perforations according to an aspect of an embodiment.

FIG. 11A is a sectional view of an example mold apparatus in a mold-open position.

FIG. 11B is a sectional view of the mold apparatus of FIG. 11A in a mold-closed position.

FIG. 12A is a sectional view of the mold apparatus of FIG. 11A with a portion of the garment of FIG. 1 positioned in the mold apparatus according to an aspect of an embodiment.

FIG. 12B is a sectional view of the mold apparatus of FIG. 11B with a portion of the garment of FIG. 1 positioned in the mold apparatus according to an aspect of an embodiment.

FIG. 13A is a sectional view of another example mold apparatus in a mold-closed position.

FIG. 13B is a sectional view of the mold apparatus of FIG. 13A with a portion of the garment of FIG. 1 positioned in the mold apparatus according to an aspect of an embodiment.

FIG. 14 is an exploded view of another example housing enclosing an example electronics module.

FIG. 15 is a top view of an example housing body of the housing of FIG. 14.

FIG. 16 is a sectional view of another example mold apparatus with the housing of FIG. 14 positioned in the mold apparatus according to an aspect of an embodiment.

FIG. 17 is an exploded view of another example housing enclosing an example electronics module.

FIG. 18A is a sectional view of the housing of FIG. 17 embedded in an over-molded enclosure, with an example actuator in a home position.

FIG. 18B is a sectional view of the housing of FIG. 17 embedded in an over-molded enclosure, with an example actuator in an actuating position.

Further aspects and features of the embodiments described herein will appear from the following description taken together with the accompanying drawings.

### DETAILED DESCRIPTION OF THE EMBODIMENTS

Various articles, apparatuses, and methods will be described below to provide an example of an embodiment of the claimed subject matter. No embodiment described below limits any claimed subject matter and any claimed subject matter may cover articles, apparatuses, or methods that differ from those described below. The claimed subject matter is not limited to articles, apparatuses, or methods having all of the features of any one article, apparatus, or method described below or to features common to multiple or all of the articles, apparatuses, or methods described below. It is possible that an article, apparatus, or method described below is not an embodiment that is recited in any claimed subject matter. Any subject matter disclosed in an article, apparatus, or method described below that is not claimed in this document may be the subject matter of another protective instrument, for example, a continuing patent application, and the applicants, inventors or owners do not intend to abandon, disclaim or dedicate to the public any such subject matter by its disclosure in this document.

Furthermore, it will be appreciated that for simplicity and clarity of illustration, where considered appropriate, reference numerals may be repeated among the figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures, and components have not been described in detail so as not to obscure the embodiments described herein. Also, the description is not to be considered as limiting the scope of the embodiments described herein.

It should also be noted that the terms “coupled” or “coupling” as used herein can have several different meanings depending in the context in which these terms are used. For example, the terms coupled or coupling can have a mechanical, electrical, or communicative connotation. For example, as used herein, the terms coupled or coupling can indicate that two elements or devices can be directly connected to one another or connected to one another through one or more intermediate elements or devices via an electrical element, electrical signal, or a mechanical element depending on the particular context. Furthermore, the term “communicative coupling” may be used to indicate that an element or device can electrically, optically, or wirelessly send data to another element or device as well as receive data from another element or device.

It should also be noted that, as used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

It should be noted that terms of degree such as “substantially”, “about” and “approximately” as used herein mean a reasonable amount of deviation of the modified term such that the end result is not significantly changed. These terms of degree may also be construed as including a deviation of the modified term if this deviation would not negate the meaning of the term it modifies.

Furthermore, any recitation of numerical ranges by endpoints herein includes all numbers and fractions subsumed within that range (e.g., 1 to 5 includes 1, 1.5, 2, 2.75, 3, 3.90, 4, and 5). It is also to be understood that all numbers and fractions thereof are presumed to be modified by the term “about” which means a variation of up to a certain amount of the number to which reference is being made if the end result is not significantly changed.

Described herein are example embodiments of garments with rigid or semi-rigid articles secured thereto, and methods for securing the articles to the garments. The garments may be activewear worn for physical activity, and the articles may be components of a bio-signal acquisition device for monitoring an individual's physiological state during physical activity. In some examples, the garment is a compression garment and the article is a housing enclosing an electronics module for receiving and processing signals indicative of a user's physiological state.

It will be appreciated that the teachings described herein are applicable to other types of garments and rigid or semi-rigid articles. For example, the garments may comprise different types of apparel, such as shirts, tank tops, vests, shoulder harnesses, pants, shorts, belts, and/or bands, and the articles secured to the garments may comprise components of, for example, accelerometers, gyroscopes, haptic feedback systems, GPS systems, or any other components or structures that may benefit from being secured to a textile.

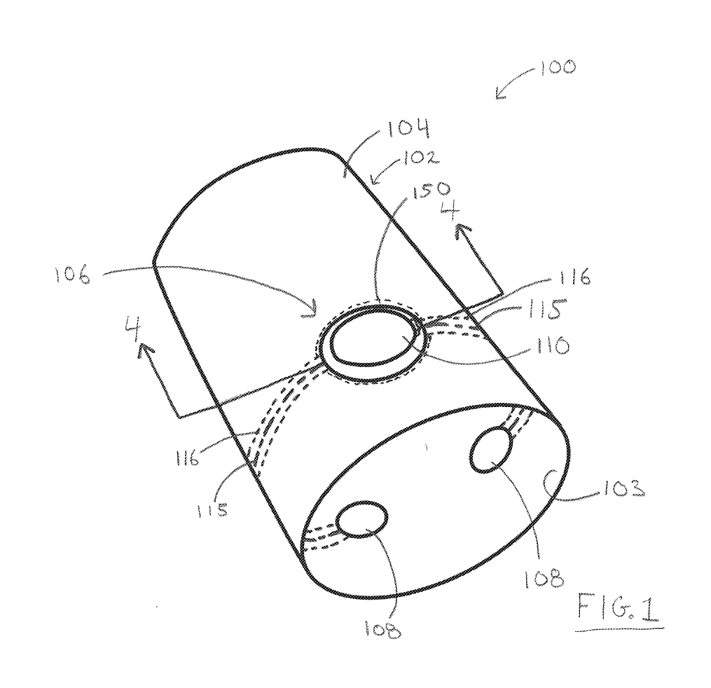

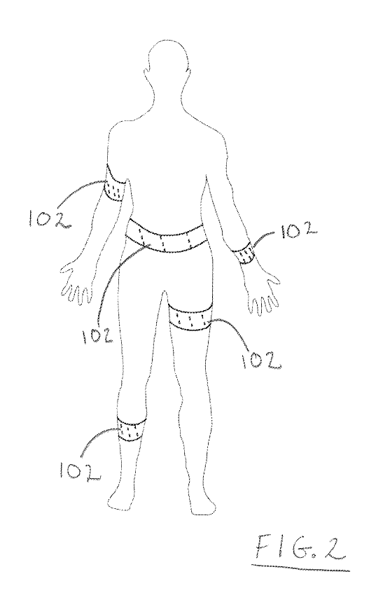

Referring to FIG. 1, an example garment 100 is shown. In the example illustrated, the garment 100 includes a flexible garment body 102. The garment body 102 can be removeably securable to a skin surface region of a user, with an inner skin-facing surface 103 of the garment body 102 positioned to make contact with the skin surface region. In the example illustrated, the garment body 102 is a compression band and can be worn to apply compressive pressure against a user's body part. As shown in FIG. 2, the garment body 102 may be worn at various positions on a user's body such as the upper arm, lower arm, waist, thigh, or lower leg.

Referring back to FIG. 1, in the example illustrated the garment body 102 is formed from a textile 104. The textile 104 may be a fabric, cloth, or polymer material suitable for being worn in contact with a user's skin. A portion, or all, of the textile 104 can be made from breathable materials to increase comfort while a user is performing an activity. In some examples, the textile 104 can be an elastic or compressive polymer material, such as neoprene, elastane, or the like. In one example, the textile 104 can be an elastane polyester blend.

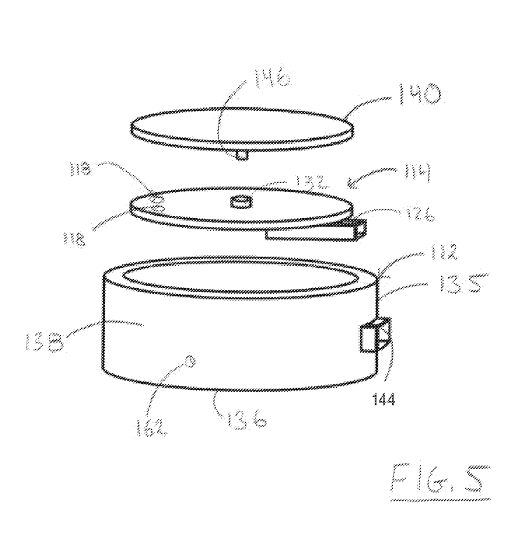

In the example illustrated, the garment 100 further includes a bio-signal acquisition device 106 secured to the garment body 102 for monitoring a user's physiological state during physical activity. The device 106 can include a plurality of electrodes 108, an enclosure 110, a housing 112 (shown in FIG. 4) embedded in the enclosure 110 and enclosing an electronics module 114 (shown in FIG. 4), and a plurality of signal-transfer lines 115 operatively coupling the electrodes 108 to the electronics module 114.

The electrodes 108 can be positioned to acquire electrical signals from a skin surface region of a user wearing the garment body 102. In the example illustrated, the device 106 is shown to include two electrodes 108. In other examples, the device 106 can include a greater number of electrodes 108, and may also include different types of sensors in place of, or in addition to, the electrodes 108 to detect various physiological events of a user performing a physical activity.

The electrodes 108 may be metallic, conductive polymers, conductive inks, or conductive fabrics or textiles such as conductive nylon, for example. In some examples, the electrodes 108 may be capacitive electrodes. The electrodes 108 can be integrated into the textile 104 of the garment body 102. In some examples, the electrodes 108 can be secured to the inner surface 103 of the garment body 102 by, for example, being printed, stitched, adhered, laminated, ironed, or over-molded onto the skin-facing surface 103 of the garment body 102. In some cases, one or more of the electrodes 108 may be provided separately from the garment body 102 as an iron-on component that a user can then apply to the garment body 102. Various other methods of affixing the electrodes 108 to the garment body 102 may be used.

Each electrode 108 may be operatively coupled through a respective signal-transfer line 115 to the electronics module 114 (shown in FIG. 4) embedded within the enclosure 110. The lines 115 can be conductive fibers, yarns, wires, or the like. In some examples, the lines 115 can be silver yarn.

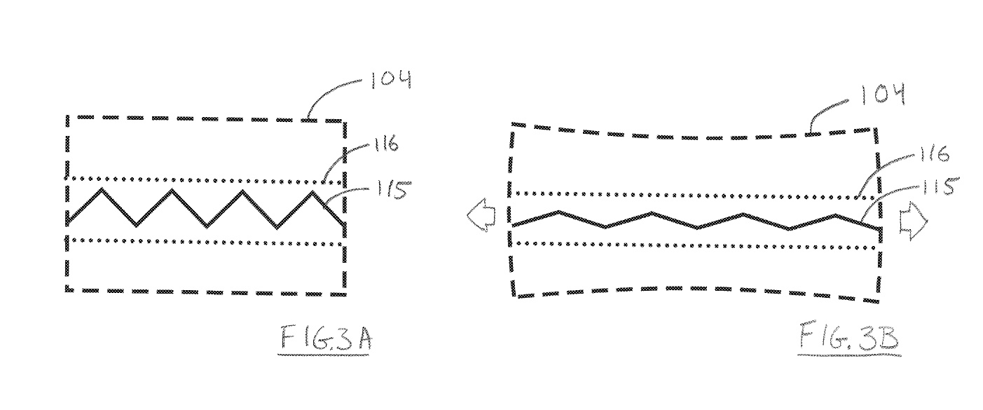

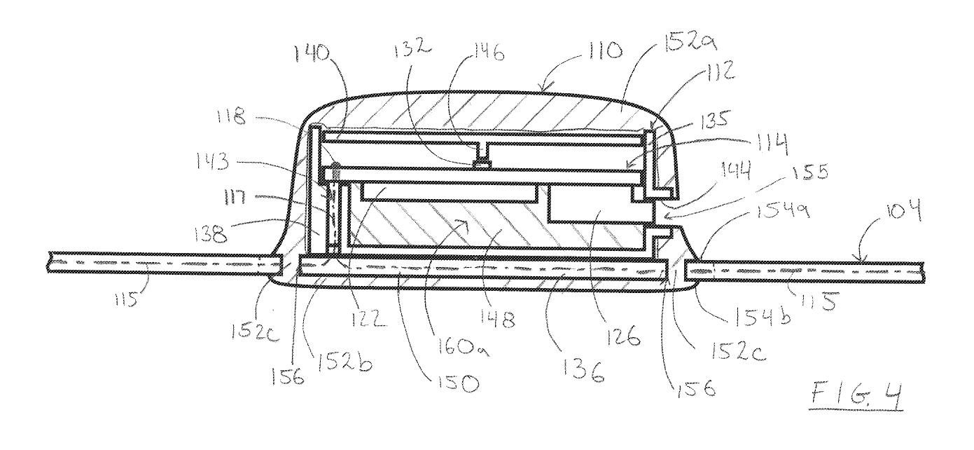

In the example illustrated, the lines 115 are integrated into the textile 104 by being woven therethrough along respective line paths 116 of the textile 104. In some examples, the textile 104 may be made from an elastic, stretchable material, whereas the lines 115 may be generally inelastic. Referring to FIG. 3A, in such examples, to accommodate stretching of the textile 104, the lines 115 can be woven through the textile 104 in a crimped pattern, such as a zig-zag or sinusoidal pattern. As shown in FIG. 3B, weaving the lines through the textile 104 in a crimped pattern permits the lines 115 to straighten out to accommodate stretching of the textile 104.

In the example illustrated, the lines 115 are insulated to minimize electrical interference from the body of the user and/or the environment. In some examples, the lines 115 may be insulated through lamination of the lines 115 with an electrically insulative material. In other examples, the lines 115 can be insulated by permeating the line paths 116 of the textile 104 along which the lines 115 extend with an insulative material, as will be described in more detail below. In still other examples, the lines 115 may be individually insulated conductors.

Referring to FIGS. 4 to 6, in the example illustrated, an end portion 117 of each line 115 extends into the housing 112 through a respective conduit 143 extending through the housing 112. The end portion 117 is operatively coupled to a respective signal input interface 118 of the electronics module 114 enclosed in the housing 112. The lines 115 can convey signals acquired from the electrodes 108 to the electronics module 114.

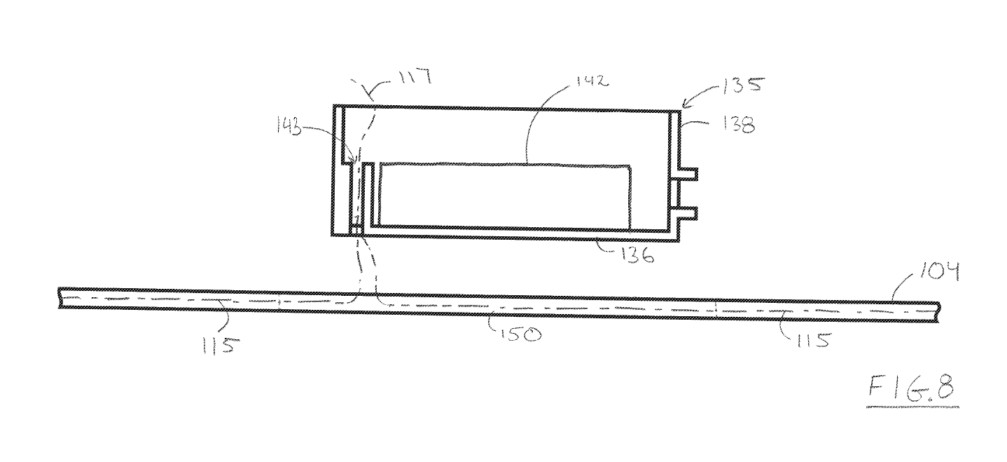

Referring to FIG. 7, in the example illustrated, the electronics module 114 includes a printed circuit board 119 operatively coupling a controller 120, a power supply 122, a memory 124, and an external connection unit 126. The controller 120 is configured to receive electrical signals from the electrodes 108 via the lines 115, and process the signals to determine, monitor, store, and/or analyze biometric features and/or other metrics for the user. In some examples, the signals from the electrodes 108 may be preprocessed (e.g., filtered, amplified, etc.) for processing by the controller 120. Such preprocessing circuitry is not shown in FIG. 7 so as not to obscure the description of the example embodiment.

In some examples, the electronics module 114 may further include a wireless communication unit 128 configured to communicate with a remote processing device 130. In such examples, the signals received from the electrodes 108 may be provided to the remote processing device 130 in raw, processed, or partially-processed form for further processing to determine, monitor, store, and/or analyze biometric features and/or other metrics for the user.

In the example illustrated, the electronics module 114 further includes an input unit for permitting a user to actuate the electronics module 114. The input unit may utilize one or more sensing technologies to permit a user to actuate the electronics module 114. In the example illustrated, the input unit can be in the form of a depressible push button 132. The button 132 can be depressed to actuate the electronics module 114. For example, the button 132 can be depressed to activate/deactivate the electronics module 114, or adjust parameters of the electronics module 114. In other examples, the input unit may be in the form of a capacitive, resistive, inductive, acoustic, and/or optical sensor configured to provide signals for actuating the electronics module 114 in response to detecting a user's intention to actuate the electronics module 114.

In some examples, the electronics module 114 may also include a haptic feedback unit 134 to provide haptic feedback to a user regarding the status of the device 106 or alerts regarding the biometrics or other metrics determined for that user. In other examples, an audio or visual feedback unit (not shown) may be provided for similar uses in addition to or in place of the haptic feedback unit 134.

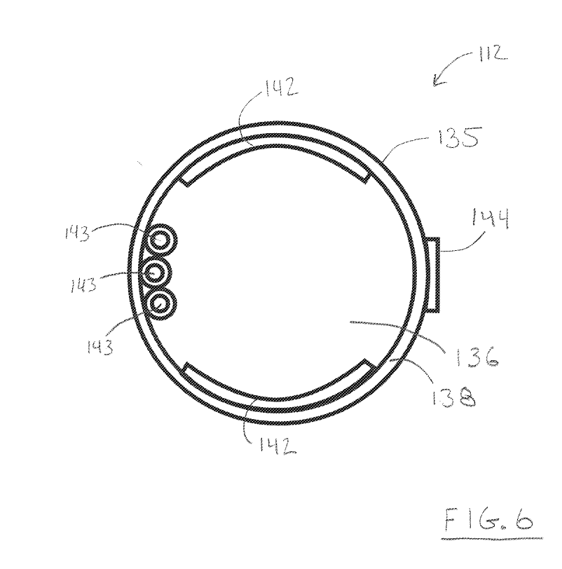

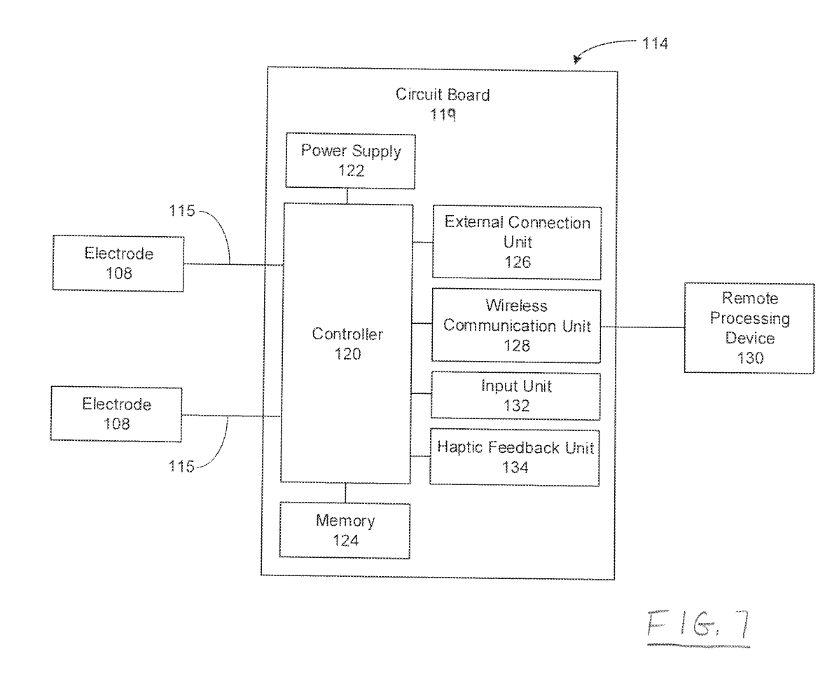

Referring back to FIG. 4, in the example illustrated, the electronics module 114 is enclosed and secured within the housing 112. Referring to FIGS. 5 and 6, in the example illustrated, the housing 112 is generally cylindrical, although the housing 112 may be of a different shape in other examples. In the example illustrated, the housing 112 includes a housing body 135 having a base 136 and a wall 138 extending upwardly from a periphery of the base 136, and a depressible disc-shaped actuator 140 enclosing the top of the housing body 135. In the example illustrated, the actuator 140 acts as a housing lid of the housing 112 and is depressible for depressing (actuating) the button 132 of the electronics module 114.

The electronics module 114 is supported within the housing 112 on one or more support structures, such as module support ledges 142, extending from the inner surfaces of the housing body 135. The lines 115 extend into the housing 112 through conduits 143 formed in the base 136 of the housing body 135 and are electrically connected to respective signal input interfaces 118 of the circuit board 119 to provide electrical signals to the controller 120.

Referring to FIG. 4, in the example illustrated, the actuator 140 is bounded about its periphery by inner surfaces of the wall 138 of the housing body 135 to prevent lateral movement of the actuator 140, and can be translated toward and away from the electronics module 114. The actuator 140 includes a plunger 146 extending downwardly from the inner surface of the actuator 140. The plunger 146 is aligned with the button 132 positioned on the upper surface of the circuit board 119 facing the actuator 140. The plunger 146 can engage and depress the button 132 to actuate the electronics module 114 in response to depression of the actuator 140. In other examples, the plunger 146 may be omitted, allowing the actuator 140 to engage and depress the button 132 directly.

In the example illustrated, the external connection unit 126 of the electronics module 114 is positioned on the lower surface (underside) of the circuit board 119 and extends through an external connection port 144 extending through the wall 138 of the housing body 135. The external connection unit 126 can be used to operatively couple an external module to the electronics module 114. In some examples, the external module may be coupled to the electronics module 114 by inserting an external cable through the external connection port 144. In some examples, the external connection unit 126 may be a Universal Serial Bus (USB) port, the external module may be a smart phone, laptop computer, or desktop computer, and the external cable may be a USB cable for powering, recharging, and/or transferring data to and/or from the electronics module 114. In other examples, the external connection unit 126 and the port 144 may be omitted.

In the example illustrated, the space 160a below the electronics module 114 between the lower surface of the circuit board 119 and the inner surface of the base 136 is filled with a potting material 148. The potting material 148 may be, for example, polyurethane or silicone. Filling the space 160a with potting material can reduce air space within the housing 112 and provide additional structural support for components of the electronics module 114.

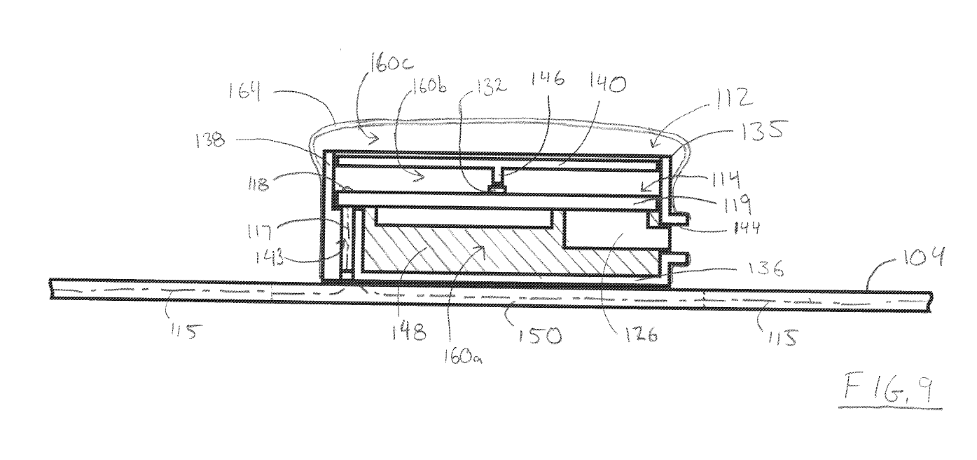

Continuing to refer to FIG. 4, in the example illustrated, the housing 112 and the enclosed electronics module 114 are secured to the textile 104 of the garment body 102 by being embedded in the enclosure 110. The enclosure 110 is undetachably molded over the housing 112 and a textile region 150 of the textile 104. An example molding process for molding the enclosure 110 over the textile region 150 and the housing 112 will be described in further detail below with reference to FIGS. 8 to 16.

Securing the housing 112 to the textile 104 by molding the enclosure 110 over the housing 112 can provide a rugged mechanical bond between the housing 112 and the textile 104, and may also mechanically stabilize the electrical connections between the lines 115 and the circuit board 119 enclosed within the housing 112. Providing a mechanically stable electrical connection between the lines 115 and the circuit board 119 may mitigate motion artifact noise, a type of high amplitude electrical noise caused by movement of electronic components that obscures useful electrical signals.

In the example illustrated, the enclosure 110 is integrally formed and comprises a dome-shaped first portion 152a molded over an exterior-facing surface 154a of the textile 104; a disc-shaped second portion 152b molded over an opposing interior skin-facing surface 154b of the textile 104; and a plurality of bonding portions 152c extending between and bonding the first and second portions 152a, 152b through the textile 104.

The bonding portions 152c may permeate the textile region 150 to bond the first and second portions 152a, 152b to one another and/or the textile region 150. The bonding portions 152c may also extend between and bond the first and second portions 152a, 152b by extending through a plurality of perforations 156 in the textile 104 adjacent and about a periphery of the base 136 of the housing body 135.

In the example illustrated, the first portion 152a of the enclosure 110 substantially encapsulates the housing 112 to environmentally seal the housing 112 and the electronics module 114 enclosed in the housing 112. Molding the enclosure 110 over the housing 112 to provide an environmental seal may prevent malfunctioning of the electronics module 114 by preventing liquids such as sweat or rain water from coming into contact with the circuit board 119 or other components of the electronics module 114. Environmentally sealing the housing 112 may also allow the garment 100 to be washed without having to detach the housing 112 or the electronics module 114.

In some examples, the enclosure 110 can include an opening 155 exposing the external connection port 144 of the housing 112, to permit coupling of the electronics module 114 and an external module by inserting an external cable through the port 144 for coupling to the external connection unit 126. The external connection unit 126 and the port 144 can be waterproof to prevent liquids from entering the housing 112 and coming into contact with the circuit board 119 or other components of the electronics module 114. As noted above, in other examples the external connection unit 126 and the port 144 may be omitted. In such cases, the opening 155 of the enclosure 110 may also be omitted, and the enclosure 110 may fully encapsulate the housing 112.

The enclosure 110 can be formed from a moldable material that, when cured, is semi-rigid and elastically deformable to allow a user to actuate the electronics module 114 through depression of the enclosure 110. In the example illustrated, depressing the center of the first portion 152a of the enclosure 110 or a region of the first portion 152a proximate the plunger 146 can push (depress) the actuator 140 of the housing 112 inwardly to press the button 132 and actuate the electronics module 114. In other examples, the enclosure 110 may be substantially rigid, and the electronics module 114 may be actuated in a manner that does not require depression of the enclosure 110.

The moldable material forming the enclosure 110 may be any material suitable for the purposes described herein. The moldable material may be a thermoplastic polymer. The thermoplastic polymer can be selected to allow for injection of the moldable material at temperatures that avoid damaging any of the over-molded components, such as the housing 112 and the textile region 150. The moldable material can also be selected to have a low viscosity prior to curing to permit the moldable material to permeate the textile 104. In some examples, the moldable material can be silicone, or a urethane rubber such as Simpact® 60A Urethane Rubber sold by Smooth-On, Inc. In some examples, the moldable material can be a room temperature vulcanization polymer. In some examples, the moldable material may be a thermosetting polymer.

In other examples, the electronics module 114 may comprise passive electrical components. For example, the electronics module 114 may comprise a coupling unit, such as a conductive plate. In such examples, the housing 112 and the remaining components of the electronics module 114 may be omitted, and the article secured to the textile region 150 by being embedded within the enclosure 110 may comprise the coupling unit. The coupling unit can be used for coupling the signal-transfer lines 115 to a detachable module for receiving and processing signals to determine, monitor, store, and/or analyze biometric features and/or other metrics for the user. The signal-transfer lines 115 may be coupled to a portion of the coupling unit enclosed by the enclosure 110. The enclosure 110 may include an opening exposing a portion of the coupling unit, and the detachable module may be detachably coupled to the exposed portion of the coupling unit.

A process for assembling the housing 112 and the electronics module 114 and securing these components to the garment body 102 will now be described.

Referring to FIG. 8, end portions 117 of the lines 115 extending from the textile 104 can be fed through respective conduits 143 into the housing body 135.

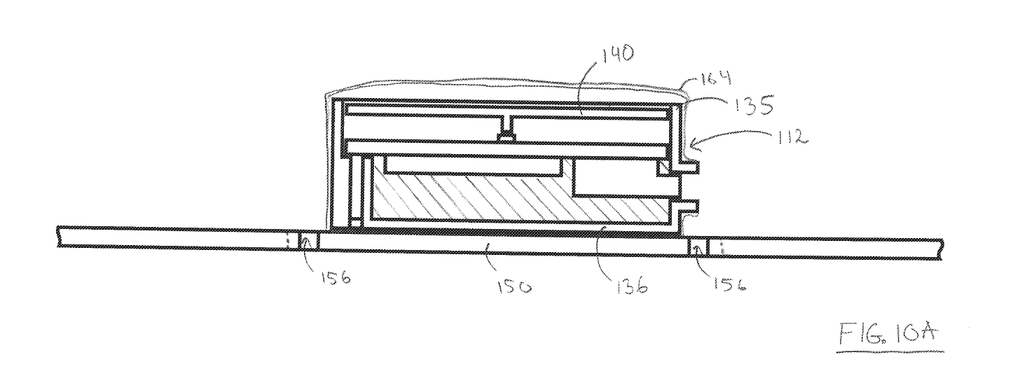

Referring to FIG. 9, the base 136 of the housing body 135 can then be positioned against the textile region 150. In some examples, an adhesive may be applied to the exterior surface of the base 136 or the textile region 150 to adhere the housing body 135 to the textile region 150. In some examples, the adhesive can be tape or urethane glue.

After the housing body 135 is adhered to the textile 104, the electronics module 114 can be positioned on the electronics module support ledges 142 (shown in FIG. 8) within the housing body 135 and secured within the housing body 135. In the example illustrated, the circuit board 119 may be secured within the housing body 135 through a friction fit. In other examples, the circuit board 119 and the housing body 135 may include complementary securement features (not shown) that permit the circuit board 119 to be snap fit within the housing body 135.

The end portions 117 of the lines 115 extending through respective conduits 143 can then be coupled to the circuit board 119 of the electronics module 114. In some examples, the end portions 117 of the lines 115 can be coupled to the electronics module 114 by being soldered or conductively adhered to respective signal input interfaces 118 of the circuit board 119. Any excess portions of the lines 115 can be trimmed.

In some embodiments, after the electronics module 114 is secured within the housing body 135 and the lines 115 are electrically connected to the circuit board 119, the potting material 148 can be injected into the space 160a between the lower surface of the circuit board 119 and the inner surface of the base 136 of the housing body 135.

Injecting the potting material 148 into the space 160a can provide additional structural support for the circuit board 119 and other components of the electronics module 114, and can seal the interface between the external connection unit 126 and the external connection port 144 to prevent water from entering the housing 112 through the port 144.

Injecting the potting material 148 into the space 160a can also remove one of the largest air spaces within the housing body 135. As will be described in more detail below, in some examples, during a subsequent pressure casting step, the housing 112 may be placed in a pressure vessel, resulting in compression of the air within the housing 112. Removing large air spaces from within the housing 112 can prevent the plunger 146 from permanently depressing the button 132 as a result of the actuator 140 being pulled inwardly toward the circuit board 119 due to compression of the air within the housing 112.

The potting material 148 can be injected through one or more injection ports 162 (shown in FIG. 5) formed in the wall 138 of the housing body 135 and between the base 136 of the housing body 135 and the circuit board 119. The wall 138 of the housing body 135 may also include one or more venting ports (not shown) to permit air to vacate the space 160a during injection of the potting material 148. In some cases, unused injection ports may be repurposed as venting ports.

After the space 160a is filled with the potting material 148, the actuator 140 can be installed by being inserted into the housing body 135 above the circuit board 119, with the plunger resting on or near the button 132. Optionally, the housing body 135 may include one or more fastening members (not shown) protruding from the inner surface near the top of the housing body 135, above the actuator 140. The fastening members may retain the actuator 140 within the housing while permitting depression of the actuator 140 toward the button 132.

In some examples, after the actuator 140 is installed, the housing 112 can be sealed by forming an encapsulating shell 164 around the housing 112. The encapsulating shell 164 can environmentally seal the housing 112 to impede moldable material forming the enclosure 110 from flowing into the housing 112 and contacting components of the electronics module 114. In some examples, the encapsulating shell 164 can comprise a sheet of vinyl surrounding the exterior surfaces of the wall 138 and the actuator 140 of the housing 112. The sheet of vinyl may be adhered to the exterior surfaces of the wall 138 adjacent the textile 104. An opening can be formed in the sheet of vinyl to expose the external connection port 144 of the housing body 135.

As noted above, in some examples, the housing 112 may be placed in a pressure vessel during a subsequent pressure casting step. The pressure vessel may operate at working pressures of approximately 3 to 4 atm, causing the initial volume of air in the space 160b between the upper surface of the circuit board 119 and the inner surface of the actuator 140 to compress to approximately ⅓ to ¼, respectively, of the initial volume. Such air compression may create a suction effect that pulls the actuator 140 and the plunger 146 inwardly toward the circuit board 119.

To minimize such a suction effect and avoid permanent depression of the button 132 due to the actuator 140 and the plunger 146 being pulled inwardly, the encapsulating shell 164 may be billowed out over the actuator 140 to define a space 160c between the upper surface of the circuit board 119 and the inner surface of the encapsulating shell 164. The volume of air in the space 160c may be larger than the volume of air in the space 160b by a factor generally proportional to the working pressure of the pressure vessel. For example, if the working pressure of the pressure vessel is approximately 3 atm, then the encapsulating shell 164 can be billowed out to provide a volume of air in the space 160c that is about three times the volume of air in the space 160b. Billowing out the encapsulating shell in this manner can allow the initial volume of air within the space 160c to compress into the space 160b during pressure casting, and may thus avoid creating the suction effect that may pull the actuator 140 inwardly toward the circuit board 119.

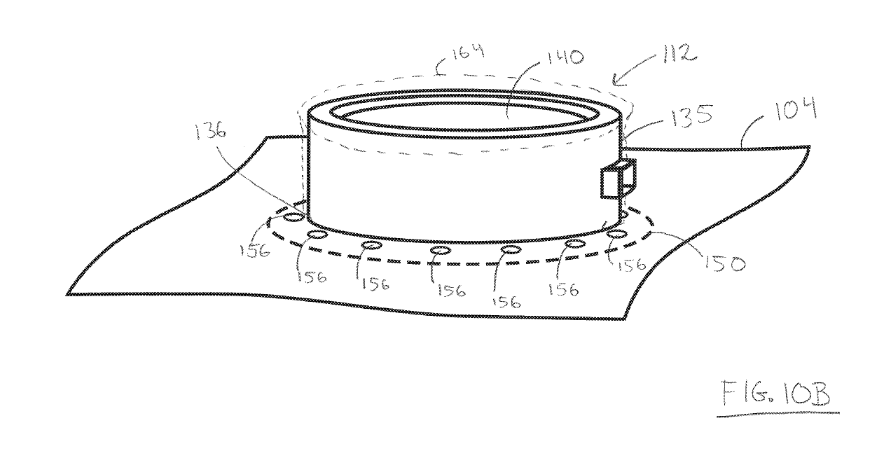

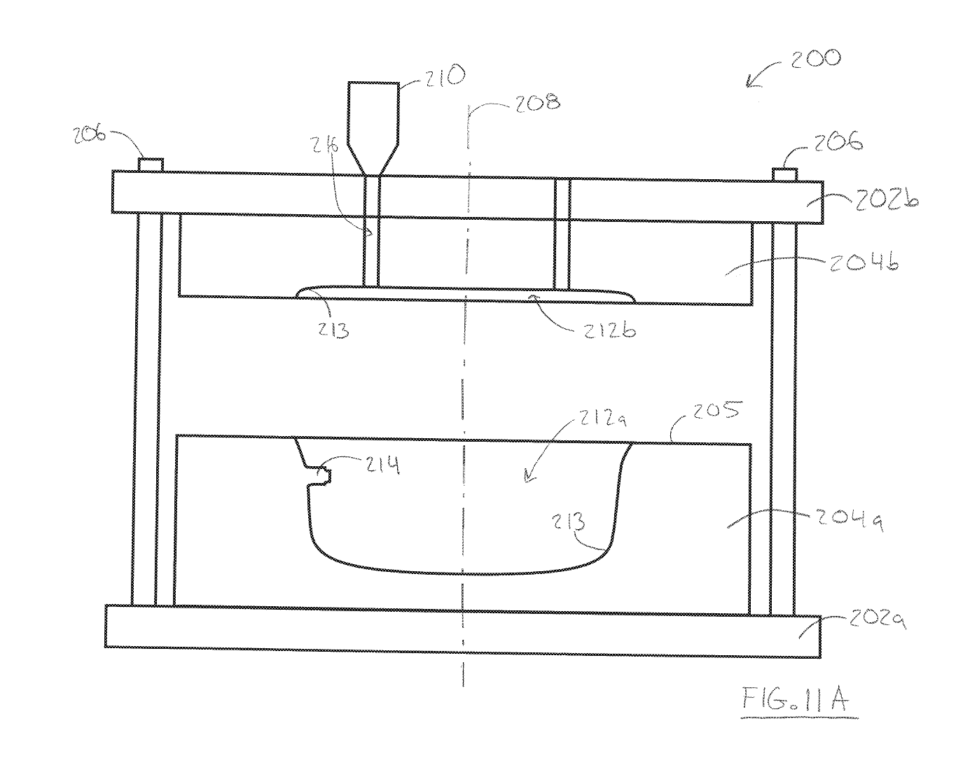

Referring to FIGS. 10A and 10B, a plurality of perforations 156 can be formed in the textile region 150 to facilitate flow of the moldable material through the textile 104. The perforations 156 can be formed adjacent and about a periphery of the base 136 of the housing body 135. In some examples, a soldering iron can be used to form the perforations 156 by melting through the textile 104. In other examples, an awl or punch may be used to form the perforations 156, for example. In other examples, the perforations 156 may be formed during manufacture of the textile 104. For example, the perforations 156 may comprise knitted eyelet patterns formed during knitting of the textile 104.

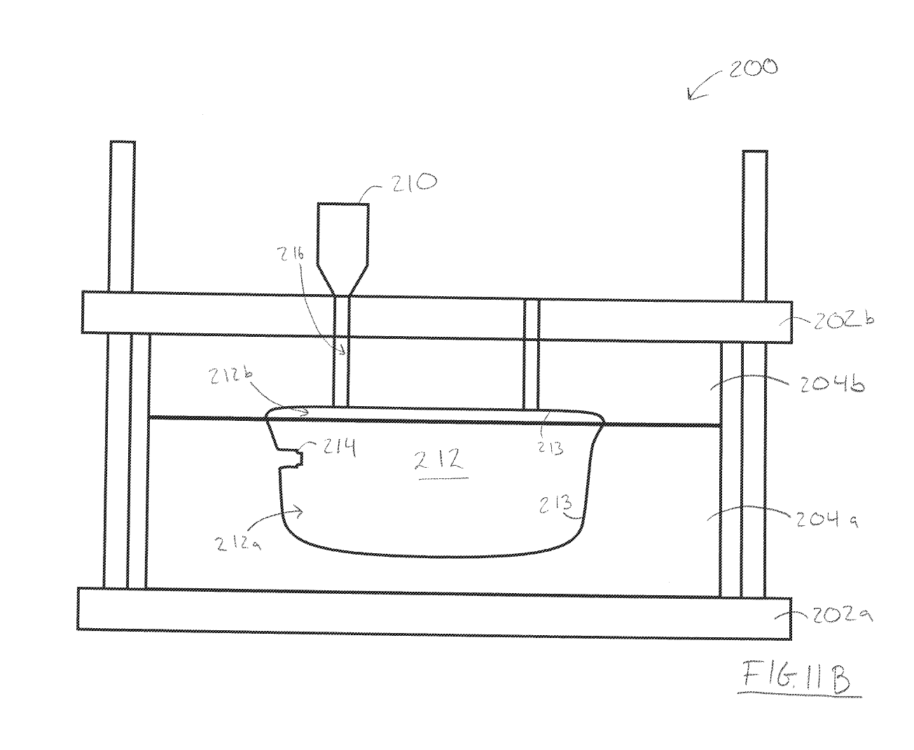

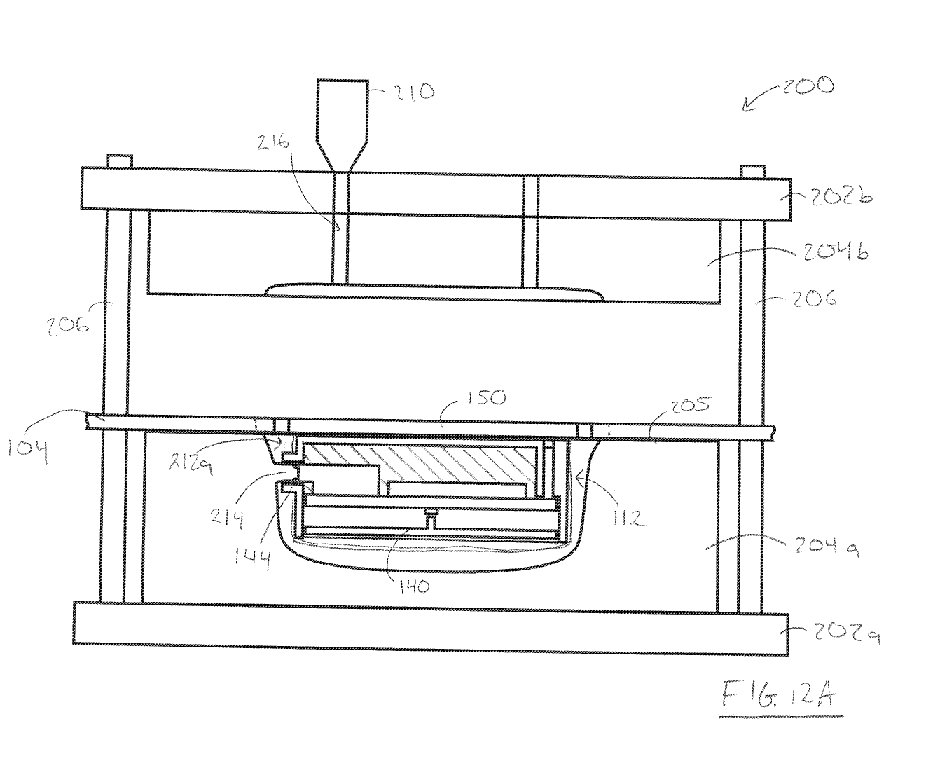

Referring to FIG. 11A, after the housing 112 is assembled and adhered to the textile region 150, a mold apparatus 200 can be used to undetachably mold the enclosure 110 over the housing 112 and the textile region 150.

In the example illustrated, the mold apparatus 200 includes a pair of platens, including a first platen 202a and a second platen 202b. The first and second platens 202a, 202b carry respective half mold portions 204a, 204b of a mold. A plurality of tie bars 206 extend generally between the first and second platens 202a, 202b for coupling the platens together by exerting a clamp load across the platens when stretched.

In the example illustrated, the first platen 202a is referred to as a stationary platen, and the second platen 202b is referred to as a moving platen. It will be appreciated that other arrangements are possible. The moving platen 202b can translate toward and away from the stationary platen 202a along a vertical axis 208 to close and open the mold. Any suitable platen actuator can be coupled to the moving platen 202b for advancing and retracting the moving platen 202b between mold-closed and mold-open positions. In some examples, the platen actuator can be driven by an electric motor. In other examples, the moving platen 202b can be manually translated toward and away from the stationary platen 202a.

When in the mold-open position (shown in FIG. 11A), the first mold portion 204a (fixed to the stationary platen 202a) and the second mold portion 204b (fixed to the moving platen 202b) are vertically spaced apart from one another. When in the mold-closed position (shown in FIG. 11B), the first mold portion 204a and the second mold portion 204b are in contact with each other and form at least one substantially sealed mold cavity 212 to be filled with moldable material (e.g., from an injection unit 210) to form the enclosure 110.

Referring to FIG. 11A, in the example illustrated, the first mold portion 204a defines a first cavity half 212a of the mold cavity 212 and the second mold portion 204b defines a second cavity half 212b of the mold cavity 212. The first cavity half 212a can be shaped to form the dome-shaped first portion 152a of the enclosure 110, and the second cavity half 212b can be shaped to form the disc-shaped second portion 152b of the enclosure 110.

The first mold portion 204a can further include one or more engagement structures such as a plug 214 for engaging a cooperating engagement structure of the housing 112 to support the housing 112 in the mold cavity 212 in a floating configuration when the mold is closed. When the housing 112 is supported in the floating configuration, unengaged portions of the housing 112 can be spaced apart from inner surfaces 213 defining the mold cavity 212, to allow the moldable material to flow around and encapsulate the housing 112.

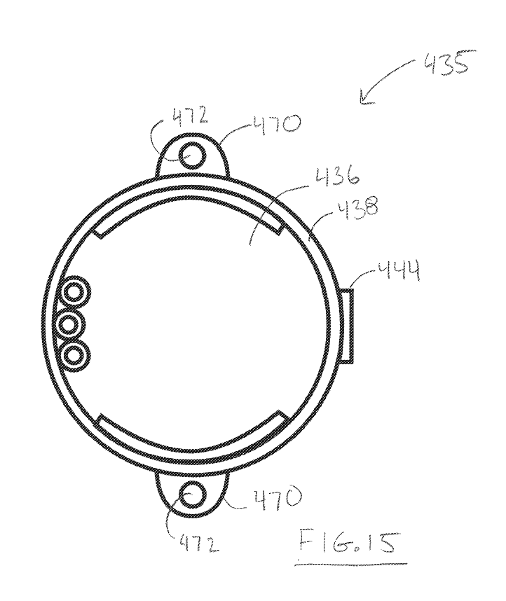

In some examples, the external connection port 144 of the housing body 135 can act as the engagement structure of the housing 112, and the plug 214 of the first mold portion 204a can be inserted into the port 144. The port 144 and the plug 214 can securely engage (or mate) to support the housing 112 in the mold cavity 212 in the floating configuration, and impede flow of the moldable material into the port 144 during the molding process. As will be described with reference to FIGS. 14 to 16, in some examples, a different engagement structure configuration can be used to support the housing 112 in the floating configuration within the mold cavity 212.

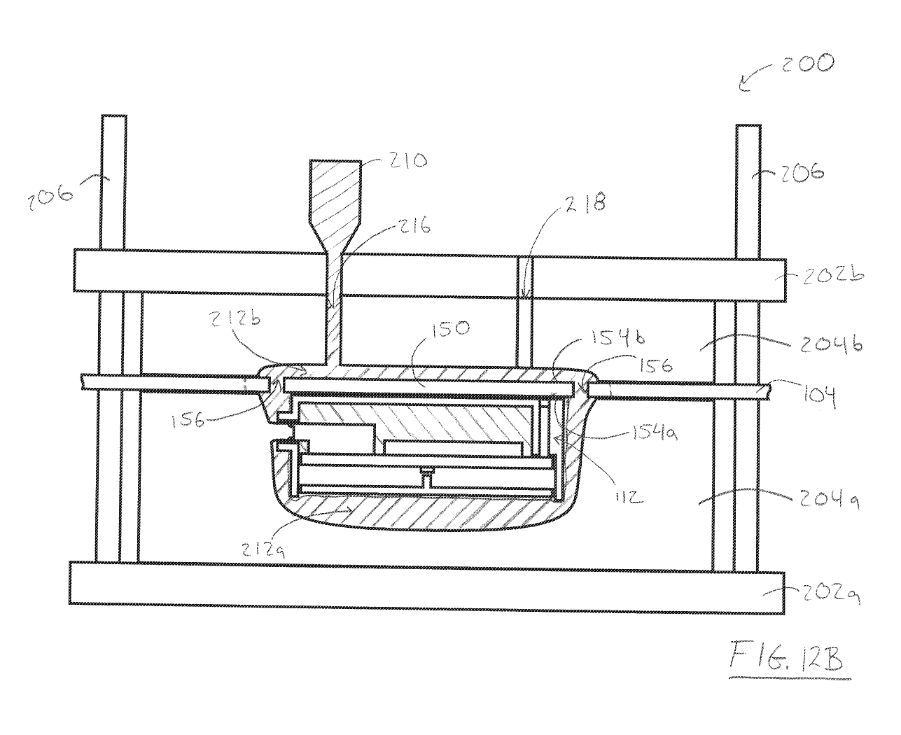

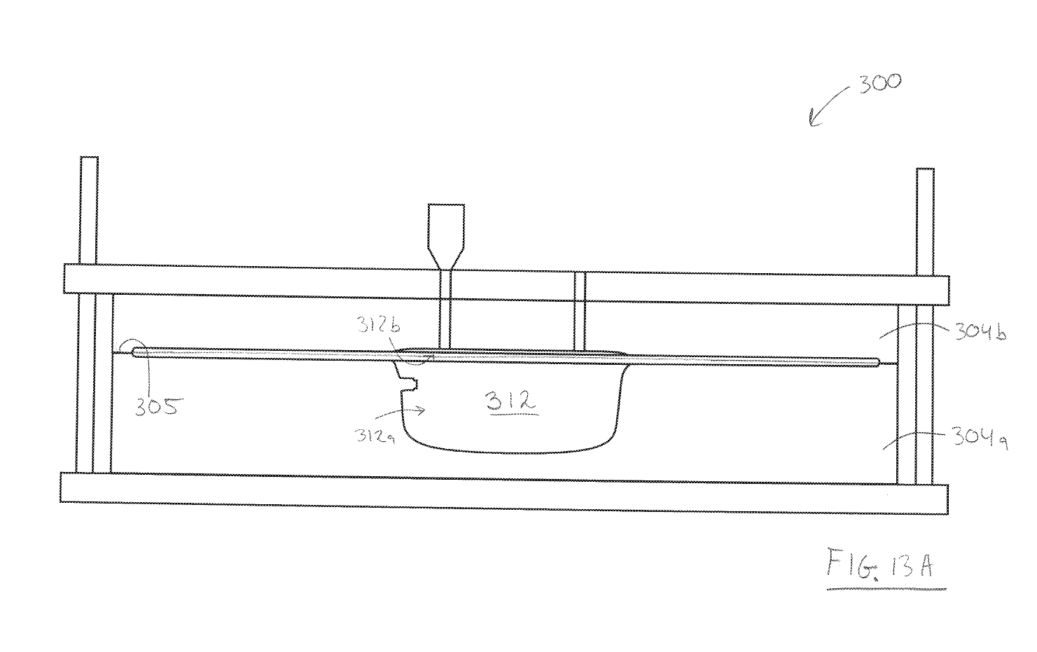

Referring to FIG. 12A, when the first and second mold portions 204a, 204b are in the mold-open position, the housing 112 can be positioned in the first cavity half 212a. In the example illustrated, the housing 112 is positioned in the first cavity half 212a by engaging the port 144 with the plug 214 so that the housing 112 can be supported in the floating configuration when the mold is closed. The housing 112 can be positioned below the textile 104, with the actuator 140 facing in the downward direction toward the inner surfaces 213 defining the first cavity half 212a of the first mold portion 204a. Positioning the housing 112 below the textile 104 may permit air bubbles formed during the molding process to float upwards and away from the outer surface of the enclosure 110, thereby reducing aesthetic imperfections in the enclosure 110.

After the housing 112 is positioned in the first cavity half 212a, the textile 104 can be laid between the first and second mold portions 204a, 204b. In the example illustrated, the textile 104 is laid on the upward-facing surface 205 of the first mold portion 204a, so that the textile region 150 extends across the first cavity half 212a of the mold cavity 212. The textile region 150 can be smoothed out to form a wrinkle-free interface across the first cavity half 212a. In some examples the textile region 150 may lie generally flat across the first cavity half 212a. In other examples, some slack may be provided in the textile 104 so that the textile region 150 may curve inwardly into the first cavity half 212a in a concave fashion.

In some examples, the textile region 150 can be smoothed out by flattening the textile 104 against the surface 205 of the first mold portion 204a. In some examples, tension can be applied across the textile 104 so that the textile 104 is taut against the surface 205 of the first mold portion 204a and the textile region 150 is generally flattened to form a continuous, wrinkle-free interface across the first cavity half 212a.

Referring to FIG. 12B, after the textile region 150 is flattened, the moving platen 202b can be advanced into the mold-closed position to clamp the textile 104 flat between the first and second mold portions 204a, 204b and substantially seal the housing 112 and the textile region 150 in the mold cavity 212. In the example illustrated, the housing 112 and the textile region 150 float within the closed mold cavity 212, in that the mold cavity 212 surrounds the housing 112 and the opposing surfaces 154a, 154b of the textile region 150 to permit the moldable material to flow around and encapsulate the housing 112 and the opposing surfaces 154a, 154b of the textile region 150.

After the mold is closed, the mold cavity 212 can be filled with moldable material. The moldable material can be injected under pressure through a sprue 216 extending through the moving platen 202b and the second mold portion 204b. The moving platen 202b and the second mold portion 204b may also include one or more vent ports 218 to allow air to vacate the mold cavity 212 during injection of the moldable material. In some embodiments, the moldable material can be vacuum degassed prior to being injected into the mold cavity 212.

The moldable material can flow through the second cavity half 212b and through the perforations 156 formed in the textile region 150 into the first cavity half 212a to embed the textile region 150 and the housing 112 in a matrix of the moldable material filling the mold cavity 212. In some embodiments, the moldable material can be forced to permeate the textile region 150 by flowing through interstices between fibers of the textile region 150. The permeating moldable material may surround and insulate the portions of the lines 115 extending through the textile region 150 and into the housing 112, and plug the conduits 143. Forcing the moldable material to permeate the textile region 150 may thus provide for a more effective environmental seal around the housing 112, and may also increase the mechanical stability of the lines 115 extending through the textile region 150 and into the housing 112, thus mitigating motion artifact noise.

In some examples, after the mold cavity 212 is filled with the moldable material, the mold apparatus 200 can be placed in a pressure vessel to pressure cast the moldable material enclosing the housing 112 and the textile region 150 within the mold cavity 212. Pressure casting the moldable material may reduce the occurrence of visible air bubble formations in the formed enclosure 110. In examples in which the moldable material is Simpact® 60A Urethane Rubber, the working pressure within the pressure vessel can be set to 3 to 4 atm. It will be appreciated that in other examples, the pressure may vary depending on the type of moldable material used, and may be set to any pressure suitable for reducing occurrence of visible air bubble formations in the formed enclosure 110.

The moldable material can then be cured to form the enclosure 110. When the moldable material is sufficiently cured, the mold can be opened and the textile 104 can be removed with the enclosure 110 undetachably molded over the textile region 150 and the housing 112 and securing the housing 112 to the textile region 150.

In some examples, prior to using the mold apparatus 200 to undetachably mold the enclosure 110 over the housing 112 and the textile region 150, the lines 115 woven through the textile 104 may be insulated. As noted above, in some examples, the lines 115 may be insulated by permeating an insulative material through the textile 104 along the line paths 116 (FIG. 1) of the textile 104 along which the lines 115 extend. In examples in which the textile 104 is made from an elastic, stretchable material, the insulative material can be selected to accommodate stretching of the textile 104. In some examples, the moldable material used to form the enclosure 110 may be used as the insulative material.

In some examples, the lines 115 may be insulated by adhering a mask to areas of the textile 104 surrounding the line paths 116 to isolate the line paths 116 and prevent the insulative material from permeating the masked areas of the textile 104. Adhesive tape may be used to form the mask. After the mask is formed on the textile 104, the insulative material can be applied to the surfaces of the textile 104 along the un-masked line paths 116. A flat-edged device, such as a spatula or a knife, may be used to evenly spread the insulative material along the line paths 116, and force the insulative material to permeate the textile 104 along the line paths 116, thereby surrounding the lines 115 woven through the textile 104. After the insulative material cures, the mask can be removed.

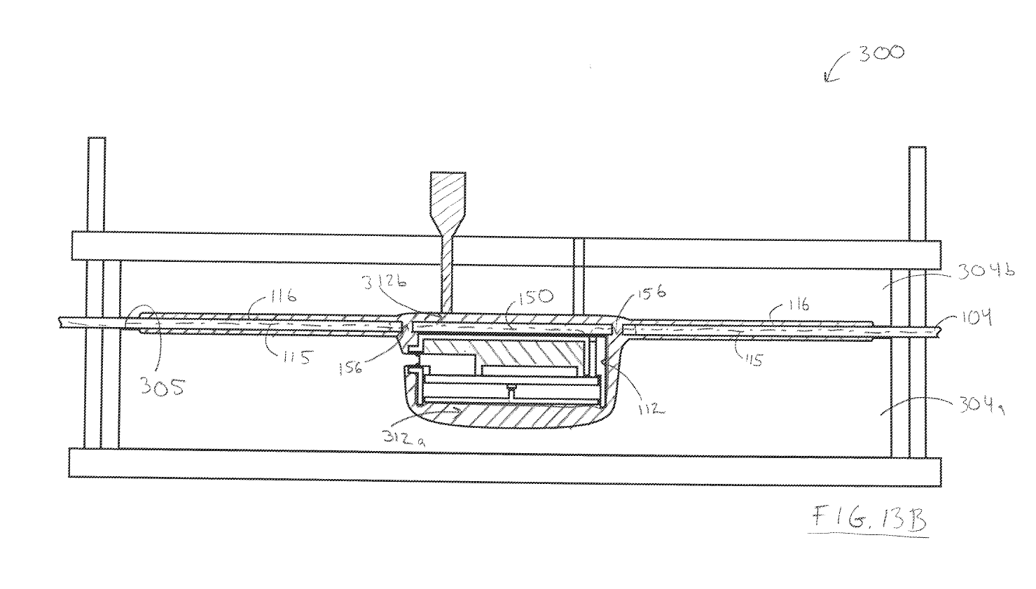

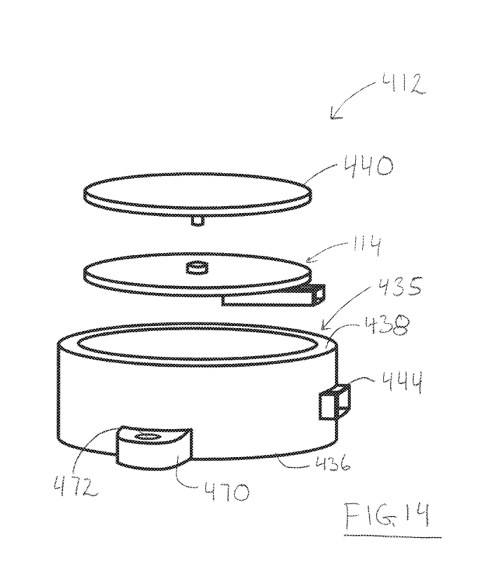

Referring to FIG. 13A, in other examples, a mold apparatus 300 may be used to insulate the lines 115. The mold apparatus 300 can be substantially similar to the mold apparatus 200, and features of the mold apparatus 300 that are similar to those of mold apparatus 200 are indicated by the same reference numerals incremented by 100. The mold apparatus 300 may be used in a manner similar to that outlined with respect to the mold apparatus 200, but may insulate the lines 115 at the same time as forming the enclosure 110.

The mold apparatus 300 includes first and second mold portions 304a, 304b defining first and second cavity halves 312a, 312b of a mold cavity 312. Similar to the mold cavity 212, the mold cavity 312 can be shaped to form the dome-shaped first portion 152a and the disc-shaped second portion 152b of the enclosure 110.

Referring to FIG. 13B, the mold cavity 312 also surrounds the line paths 116 along which the lines 115 extend through the textile 104. To form the enclosure 110 and insulate the lines 115, the housing 112 can be positioned into the mold cavity 312 as described above with respect to the mold apparatus 200. The textile 104 can then be laid on the upward-facing surface 305 of the first mold portion 304a, so that the textile region 150 and each of the line paths 116 are aligned with and extend across respective portions of the first cavity half 312a of the mold cavity 312. After the mold is closed, the mold cavity 312 can be filled with moldable material. The moldable material may be forced to flow through the perforations 156 formed in the textile region 150 and permeate the textile region 150 and the line paths 116 of the textile 104. The moldable material can then be cured to form the enclosure 110 and insulate the lines 116.

In some examples, it may be preferable to use an insulative material for insulating the lines 115 that is different from the moldable material for forming the enclosure 110. In such examples, separate mold apparatuses may be used to insulate the lines 115 and form the enclosure 110. For example, a first mold apparatus having a mold cavity for molding a first moldable material over the line paths 116 may be used to insulate the lines 115. After the first moldable material cures, a second mold apparatus, such as the mold apparatus 200, may be used to form the enclosure 110 using a different, second moldable material

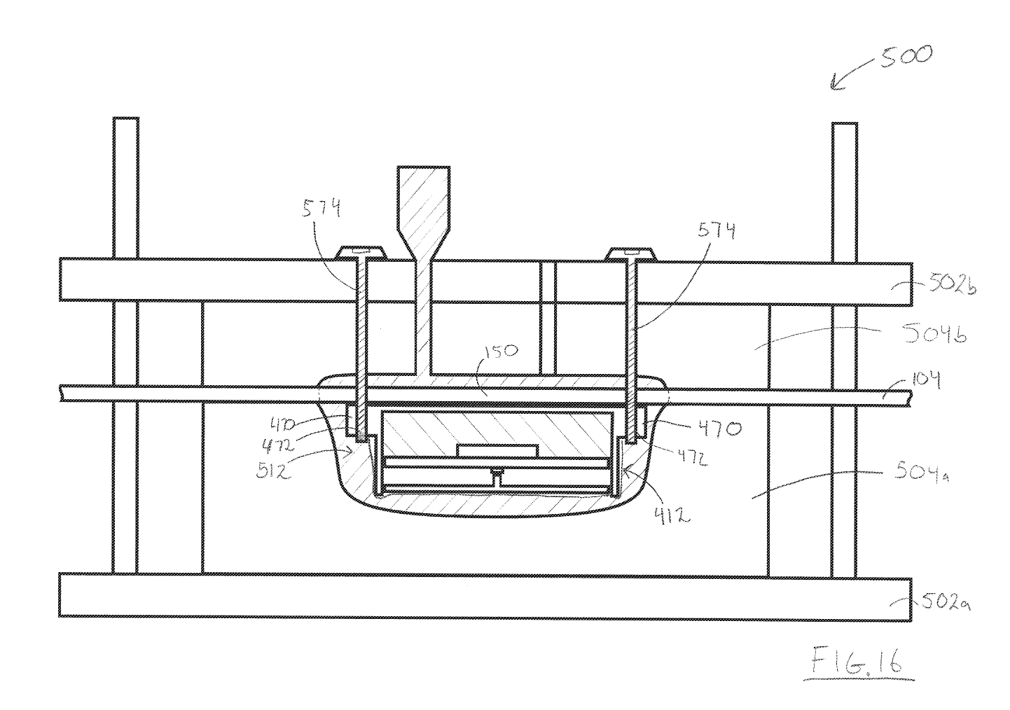

Referring to FIGS. 14 and 15, another example housing 412 for enclosing the electronics module 114 is shown. The housing 412 can be substantially similar to the housing 112, and features of the housing 412 that are similar to those of the housing 112 are indicated by the same reference numerals incremented by 300. The housing 412 can include a pair of engagement structures 470 protruding from circumferentially opposed exterior surfaces of the wall 438 near the base 436 of the housing body 435. The engagement structures 470 can include tapped holes 472 extending vertically therethrough.

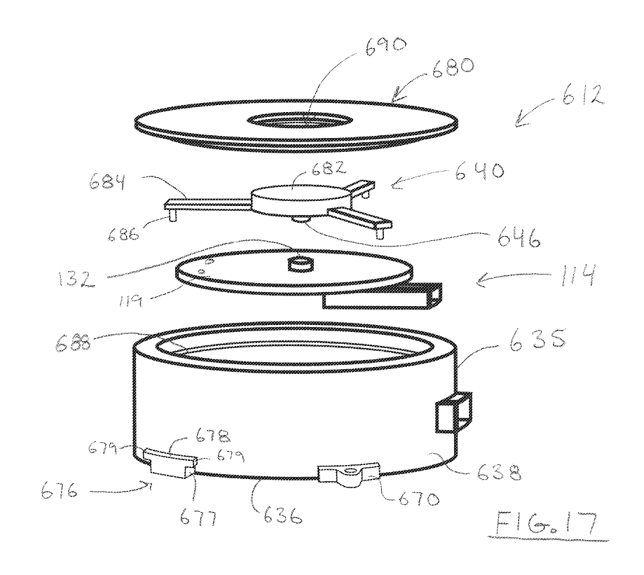

Referring to FIG. 16, the engagement structures 470 of the housing 412 can be used in place of, or in addition to, the port 444 to support the housing 412 in the floating configuration during molding of the enclosure 110 using the mold apparatus 500. The mold apparatus 500 can be substantially similar to the mold apparatus 200, and features of the mold apparatus 500 that are similar to those of mold apparatus 200 are indicated by the same reference numerals incremented by 300.

The mold apparatus 500 may be used in a manner similar to that outlined with respect to the mold apparatus 200 to form the enclosure 110, but can further include a pair of engagement structures in the form of threaded fasteners 574, such as screws. The threaded fasteners 574 can cooperate with the engagement structures 470 of the housing 412 to support the housing in the floating configuration within the mold cavity 512.

The threaded fasteners 574 can extend into the mold cavity 512 through holes formed in the movable platen 502b and the second core portion 504b. The threaded fasteners 574 can be positioned and sized to thread through the tapped holes 472 of the engagement structures 470 of the housing 412 to support the housing 412 in the mold cavity 512 in the floating configuration during molding of the enclosure 110. A pair of holes can be formed in the textile 104 to permit the threaded fasteners 574 to extend through the textile 104 to engage the tapped holes 472 of the housing 412.

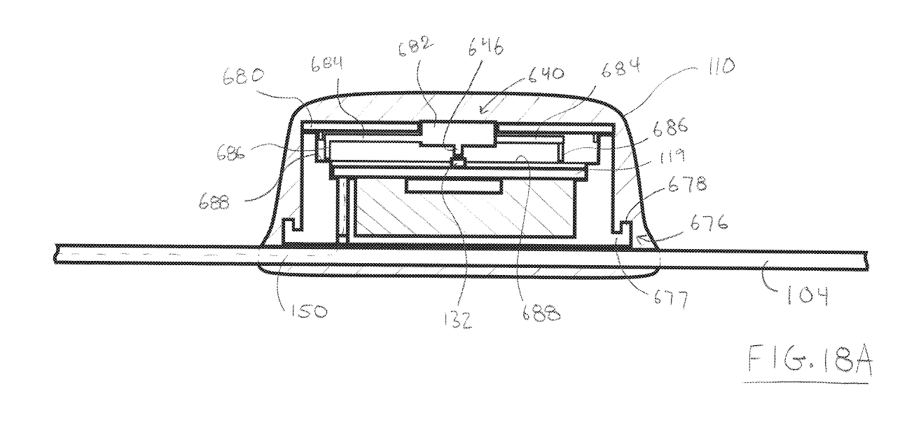

Referring to FIG. 17, another example housing 612 for enclosing the electronics module 114 is shown. The housing 612 can be substantially similar to the housing 112, and features of the housing 612 that are similar to those of the housing 112 are indicated by the same reference numerals incremented by 500.

In the example illustrated, the housing 612 includes a pair of engagement structures 670 protruding from circumferentially opposed exterior surfaces of the wall 638 near the base 636 of the housing body 635. The engagement structures 670 are substantially similar to the engagement structures 470 of the housing 412 described above. The engagement structures can be used to support the housing 612 in the floating configuration during molding of the enclosure 110 in a manner similar to that described with respect to the housing 412 using a mold apparatus, such as the mold apparatus 500.

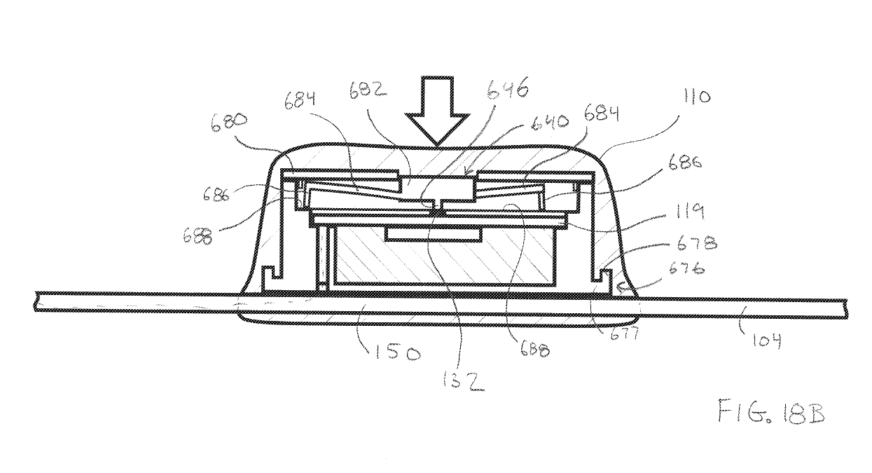

The housing 612 can further include one or more securement flanges 676. In the example illustrated, each flange 676 includes a flange body 677 protruding from exterior surfaces of the wall 638 near the base 636 of the housing body 635, and a flange head 678 spaced apart from the housing body 635 and fixed to the top surface at the distal end of the flange body 677. Each flange head 678 includes flange arm portions 679 extending past opposed lateral surfaces of the flange body 677. During molding of the enclosure 110, the moldable material can flow around and surround the flanges 676 to more securely embed the housing 612 within the enclosure 110 (see, for example, FIG. 18A).

In the example illustrated, an actuator 640 is supported within the housing 612 between the electronics module 114 and a housing lid 680 enclosing the top of the housing body 635. The actuator 640 can include a disc-shaped actuator body 682 having a plunger 646 extending downwardly from the inner surface of the actuator body 682. The actuator 640 can further include a plurality of resilient, flexible actuator arms 684 extending radially away from the actuator body 682. In the example illustrated, the actuator 640 includes three actuator arms 684 spaced equidistantly about the circumference of the actuator body 682. A different number of actuator arms 684 may be included in other examples. Each actuator arm 684 includes a support leg 686 extending downwardly at a distal end of the actuator arm 684. The support legs 686 can support the actuator 640 on support structures, such as actuator support ledges 688, extending from the inner surfaces of the housing body 135.

Referring to FIG. 18A, when assembled, the actuator 640 is positioned above the circuit board 119, with the actuator legs 686 resting the actuator support ledges 688 and the actuator body 682 positioned so that the plunger 646 is aligned with the button 132 of the circuit board 119. In the example illustrated, the actuator arms 684 bias the actuator body 682 in a home position in which the plunger 646 rests on (or is spaced apart from) the button 132 of the circuit board 119 without depressing (actuating) the button 132. The actuator arms 684 can flex elastically to permit translation of the actuator body 682 from the home position into an actuating position (FIG. 18B), in which the plunger 646 is moved inwardly and actuates the button 132 of the circuit board 119.

In the home position, a portion of the actuator body 682 can extend through an aperture formed in the housing 612. In the example illustrated, a top portion of the actuator body 682 extends through the aperture 690 (see FIG. 17) formed in the housing lid 680.

Referring to FIG. 18B, a user can actuate the electronics module 114 enclosed within the housing 612 through depression of the enclosure 110. In the example illustrated, a user can actuate the electronics module 114 by depressing the center of the first portion 152a of the enclosure 110. Depressing the center of the first portion 152a can elastically deform the enclosure 110 and push the top portion of the actuator body 682 inwardly through the aperture 690 from the home position into the actuating position. Once the user ceases depressing the enclosure 110, the enclosure 110 can return to its original shape, permitting the biasing actuator arms 684 to urge the actuator body 682 back into the home position (FIG. 17A).

While the applicant's teachings described herein are in conjunction with various embodiments for illustrative purposes, it is not intended that the applicant's teachings be limited to such embodiments. On the contrary, the applicant's teachings described and illustrated herein encompass various alternatives, modifications, and equivalents, without generally departing from the embodiments described herein.

1. A method for securing a rigid or semi-rigid article to a textile, the method comprising:
a) positioning the article in a mold cavity of a mold;
b) laying the textile between opposed mold portions for forming the mold cavity with a textile region of the textile extending across the mold cavity;
c) closing the mold to clamp the textile between the opposed mold portions and substantially seal the article and the textile region in the mold cavity;
d) filling the mold cavity with moldable material; and
e) curing the moldable material to form an enclosure undetachably molded over the article and the textile region and embedding the article.

2. The method of claim 1, wherein the enclosure environmentally seals the article.

3. The method of claim 1, wherein the mold cavity surrounds opposing surfaces of the textile region when the mold is closed, and the enclosure is molded over the opposing surfaces.

4. The method of claim 1, wherein the filling step further comprises forcing the moldable material to permeate the textile region.

5. The method of claim 1, further comprising, prior to the filling step, forming perforations in the textile region to facilitate flow of the moldable material through the textile region during the filling step.

6. The method of claim 1, wherein the laying step further comprises smoothing out the textile region.

7. The method of claim 1, wherein the article comprises a housing enclosing an electronics module.

8. The method of claim 7 further comprising, prior to the filling step, positioning a base of the housing against the textile region, and supporting the base against the textile region during the filling step.

9. The method of claim 8, further comprising, prior to the filling step, forming perforations adjacent a periphery of the base through the textile region for permitting flow of the moldable material through the textile region during the filling step.

10. The method of claim 7 further comprising, prior to the closing step, forming an encapsulating shell around the housing, the shell impeding moldable material from flowing into the housing during the filling step.

11. The method of claim 7, wherein the positioning step further comprises engaging an engagement structure of the housing with a cooperating engagement structure of the mold to support the housing within the mold cavity in a floating configuration in which unengaged portions of the housing are spaced apart from inner surfaces defining the mold cavity when the mold is closed.

12. The method of claim 7, further comprising, prior to the filling step, injecting a potting material into the housing to reduce air space within the housing.

13. The method of claim 1, further comprising, after the filling step, placing the enclosure inside a pressure vessel having a pressure suitable to reduce occurrence of visible air bubble formations in the formed enclosure.

14. A garment comprising:
a) a textile;
b) a rigid or semi-rigid article; and
c) an enclosure undetachably molded over the article and a textile region of the textile, and embedding the article.

15. The garment of claim 14, wherein the enclosure environmentally seals the article.

16. The garment of claim 14, wherein the enclosure is integrally formed and comprises a first portion and a second portion molded over opposing surfaces, respectively, of the textile region, and bonding portions extending between the first and second portions through the textile.

17. The method of claim 16, wherein the bonding portions permeate the textile region.

18. The garment of claim 16, wherein the bonding portions extend between the first and second portions through perforations in the textile region.

19. The garment of claim 18, wherein a surface of the article is adhered to the textile region and the perforations are adjacent a periphery of the surface.

20. The garment of claim 14, wherein the article comprises a housing enclosing an electronics module.

21. The garment of claim 20, wherein depression of the enclosure actuates the electronics module.

22. The garment of claim 21, wherein the housing comprises a base adjacent the textile region, a wall extending upwardly from a periphery of the base, and an actuator enclosing a top of the housing, and wherein the actuator is depressible to actuate the electronics module through depression of the enclosure.

23. The garment of claim 21, wherein an actuator is supported within the housing, a portion of the actuator extending through an aperture of the housing and depressible to actuate the electronics module through depression of the enclosure.

24. The garment of claim 20, wherein the enclosure comprises an opening exposing a port of the housing, the port for operatively coupling an external module to the electronics module.

25. The garment of claim 14, wherein the enclosure is formed from a cured moldable material.
